(19) United States
(12) Patent Application Publication
(10) Pub. No.: US 2015/0120225 A1
(43) Pub. Date: Apr. 30, 2015

(54) APPARATUS AND METHOD FOR DETERMINING DEGRADATION OF HIGH-VOLTAGE VEHICLE BATTERY

(71) Applicant: HYUNDAI MOBIS CO., LTD., Yongin-si (KR)

(72) Inventor: Tae Kwon KIM, Yongin-si (KR)

(73) Assignee: HYUNDAI MOBIS CO., LTD., Yongin-si (KR)

(21) Appl. No.: 14/087,606

(22) Filed: Nov. 22, 2013

(30) Foreign Application Priority Data
Oct. 31, 2013 (KR) 10-2013-0131010

(51) Int. Cl. G01R 31/36

(52) U.S. Cl. CPC G01R 31/3679; G01R 31/3624; G01R 31/3648
USPC 702/63

(57) ABSTRACT

Provided are an apparatus and method for determining degradation of a high-voltage vehicle battery, and the apparatus for determining degradation of a high-voltage vehicle battery is configured to measure a battery state of health (SOH) according to a preset estimation calculation, thereby minimizing a battery degradation estimation error. According to the present invention, it is possible to calculate a capacity of a battery only using a current value and a state of charge (SOC) change value to estimate an SOH of the battery, thereby simplifying an algorithm for the estimation. In particular, it is also advantageously possible to estimate a battery SOH through a first estimation algorithm, compare the estimated battery SOH with a threshold value, determine whether to perform re-estimation, and if the re-estimation is determined, re-estimate the battery SOH through a second estimation algorithm, using a least mean square method, thereby minimizing an error in a battery SOH estimation value.

### CROSS-REFERENCE TO RELATED APPLICATIONS

This application claims priority under 35 U.S.C. §119 to Korean Patent Application No. 10-2013-0131010, filed on Oct. 31, 2013, the disclosure of which is incorporated herein by reference in its entirety.

### TECHNICAL FIELD

The present invention relates to an apparatus and method for determining degradation of a high-voltage vehicle battery, and more particularly, to an apparatus and method for estimating a state of health (SOH) of a high-voltage vehicle battery pack.

### BACKGROUND

In general, an electric vehicle or a hybrid electric vehicle (hereinafter referred to as an electric drive vehicle) is a vehicle that uses electric energy stored in a battery in an electric drive mode.

Since the electric drive vehicle is driven using energy charged in the battery, it is very important to find out a state of charge (SOC) of the battery. Accordingly, a technology for checking an SOC of the battery to inform a driver of relevant information, including a driving range, has been actively developed.

As an example, there is a method for measuring a voltage of a battery during charge and discharge of the battery, estimating a no-load battery open circuit voltage (OCV) from the measured voltage, and mapping the SOC corresponding to the estimated OCV with reference to an SOC table for each OCV.

However, the described method has a limitation in that, since the battery voltage is considerably different from an actual voltage because of IR drop during the charge and discharge of the battery, an accurate SOC cannot be acquired if the difference is not corrected.

For reference, IR drop is an abrupt drop in the voltage at the beginning of discharging a battery connected to a load or charging a battery from an external source. That is, the battery voltage drops rapidly at the beginning of discharging while the battery voltage rises rapidly at the beginning of charging.

As another example, there is also a method for integrating a charge and discharge current of a battery to estimate an SOC of the battery. However, the method has a limitation in that the accuracy of the SOC becomes poorer with time by continuously accumulating measurement errors during measurement of the current.

Another parameter indicating a battery state, other than an SOC, is a state of health (SOH). The SOH is a parameter that quantitatively indicates variation of capacity characteristics of a battery due to an aging effect, which may indicate how much the capacity of the battery is reduced.

Accordingly, an appropriate battery replacement timing may be found on the basis of the SOH, and over-charging and over-discharging of the battery may be prevented by controlling a charge and discharge capacity of the battery according to the use time of the battery.

Since the variation of capacity characteristics of the battery is reflected by variation of internal resistance, the SOH may be estimated on the basis of internal resistance and temperature of the battery.

That is, a lookup table for SOH mapping may be acquired by measuring the capacity of the battery by internal resistance and temperature in a charge and discharge experiment, and the SOH of the battery may be estimated by measuring the internal resistance and temperature of the battery in an actual use environment and mapping the SOH corresponding to the internal resistance and temperature from the lookup table.

However, in the SOH estimation method, it is most important to accurately find out the internal resistance of the battery.

It is actually impossible to directly measure the internal resistance of the battery during charge and discharge of the battery. Thus, typically, the battery's internal resistance may be indirectly calculated by measuring the voltage and the charge and discharge current of the battery and then using the ohm's law.

However, the voltage of the battery is different from an actual voltage because of the IR drop, and the current of the battery has a measurement error. Thus, the internal resistance simply calculated by the ohm's law and the SOH estimated from the calculated internal resistance have low reliability.

The related art may include a base map establishment operation of finding out a change rate of the charge capacity with respect to a certain variation in the voltage during slow charging according to an SOH of a high-voltage battery, a data acquisition operation of acquiring a charge capacity and a voltage of the high-voltage battery during the slow charging, in a vehicle equipped with the high-voltage battery, a change rate calculation operation of calculating the change rate of the charge capacity with respect to a certain variation in the voltage from the charge capacity and voltage acquired by the vehicle, and an SOH determination operation of comparing the change rate of the charge capacity with respect to the certain variation in the voltage calculated in the change rate calculation operation with the change rate of the charge capacity with respect to the certain variation in the voltage according to the SOH in the base map establishment operation to determine an SOH.

That is, the related art includes finding out the change rate of the charge capacity with respect to the certain variation in the voltage during the slow charging of the high-voltage battery equipped in the vehicle, comparing the rate of change with a base map including the change rate of the charge capacity with respect to the certain variation in the voltage during the slow charging according to the degradation of a high-voltage battery having the same specification.

In addition, as shown in FIG. 1, the related art includes a first operation S101 of measuring a current, a voltage, and a temperature of a high-voltage battery equipped in a vehicle, a second operation S102 of determining whether the measured temperature and current of the battery satisfies a predetermined SOH determination condition, a third operation S103 of finding out a change rate of the charge capacity with respect to a certain variation in the voltage of the high-voltage battery if the SOH determination condition is satisfied in the second operation, and a fourth operation S104 of comparing the change rate of the charge capacity with respect to the certain variation in the voltage calculated in the third operation S103 with data established by measuring the change rate of the charge capacity with respect to a certain variation in the voltage according to an SOH of each high-voltage battery having the same specification to find out an SOH of a high-voltage battery equipped in the vehicle.

That is, the third operation S103 corresponds to the data acquisition operation and the change rate calculation operation, and the fourth operation S104 corresponds to the SOH determination operation.

Here, the change rate of the charge capacity with respect to a certain variation in the voltage in the third operation S103 and the fourth operation S104 may be found out in a voltage range where voltage change characteristics with respect to the SOC is the same, irrespectively of the SOH of the high-voltage battery.

However, the related art has a limitation in that a lot of test results are required to table the change rate of the charge capacity with respect to change in the voltage of the battery, and an error is generated when the change rate of the charge capacity with respect to change in the voltage of the battery is not matched with any in the table.

### SUMMARY

Accordingly, the present invention provides an apparatus and method for determining degradation of a high-voltage vehicle battery that can measure an SOH of the battery according to a preset estimation calculation, thereby minimizing an error in estimating degradation of the battery.

In one general aspect, an apparatus for determining degradation of a high-voltage vehicle battery includes: a first SOH estimation calculation unit configured to estimate a first state of health (SOH) on the basis of a variation in a state of charge (SOC) of the high-voltage vehicle battery and an amount of electric charge during a specific time calculated according to a flow of a current during charge and discharge of the high-voltage vehicle battery; a second SOH estimation calculation unit configured to estimate a second battery SOH through a least mean square method on the basis of the variation in the battery SOC and the amount of electric charge during the specific time corresponding to the estimated first battery SOH; and a control unit configured to allow the first SOH estimation calculation unit and the second SOH estimation calculation unit to estimate the battery SOHs, respectively, in order to minimize an error in the finally estimated battery SOH.

In another general aspect, a method of determining degradation of a high-voltage vehicle battery includes: estimating a first battery state of health (SOH) on the basis of a variation in a state of charge (SOC) of the high-voltage vehicle battery and an amount of electric charge during a specific time calculated according to a flow of a current during charge and discharge of the high-voltage vehicle battery; and estimating a second battery SOH through a least mean square method on the basis of the variation in the battery SOC and the amount of electric charge during the specific time corresponding to the estimated first battery SOH.

Other features and aspects will be apparent from the following detailed description, the drawings, and the claims.

### BRIEF DESCRIPTION OF THE DRAWINGS

FIG. 1 is a view showing the related art.

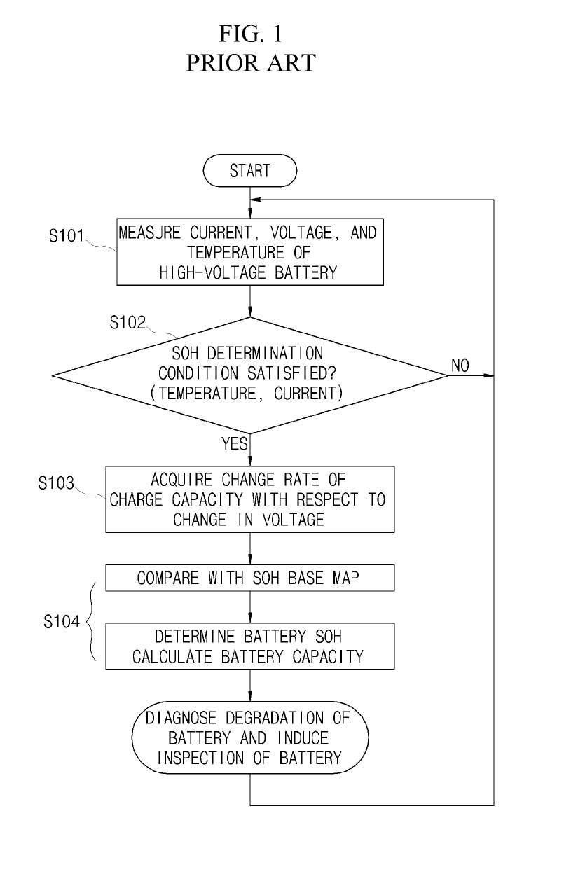

FIG. 2 is a block diagram showing an apparatus for determining degradation of a high-voltage vehicle battery according to an embodiment of the present invention.

FIG. 3 is a view showing a relation between an amount of electric charge and an SOC variation.

FIG. 4 is a flowchart showing a method of determining degradation of a high-voltage vehicle battery according to an embodiment of the present invention.

### DETAILED DESCRIPTION OF EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” or “comprising,” when used in this specification, specify the presence of stated features, integers, operations, operations, elements, and/or components, but do not preclude the presence or addition of one or more other features, integers, operations, operations, elements, components, and/or groups thereof.

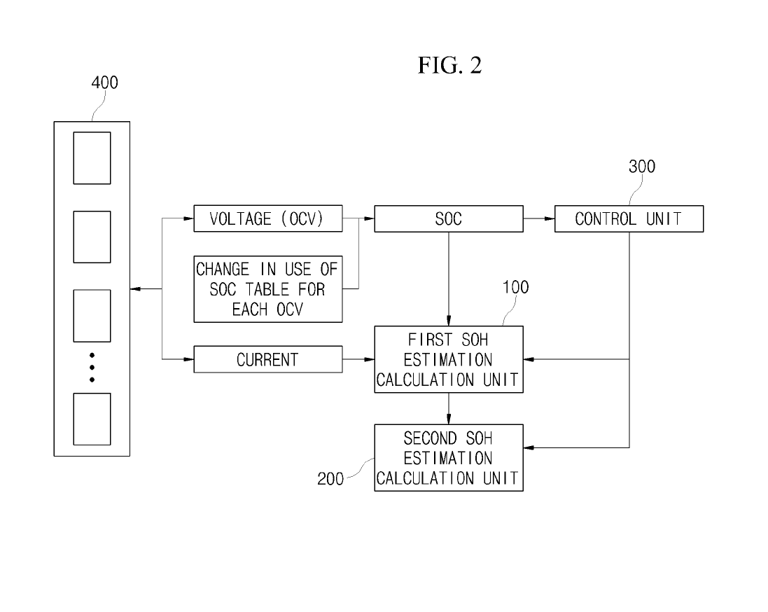

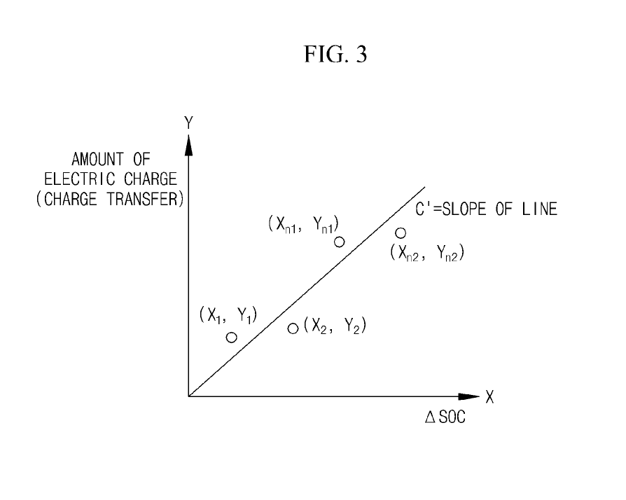

An apparatus for determining degradation of a high-voltage vehicle battery according to an embodiment of the present invention will be described below with reference to FIGS. 2 and 3. FIG. 2 is a block diagram showing an apparatus for determining degradation of a high-voltage vehicle battery according to an embodiment of the present invention, and FIG. 3 is a view showing a relation between an amount of electric charge and an SOC variation.

As shown in FIG. 2, an apparatus for determining degradation of a high-voltage vehicle battery of the present invention includes a first SOH estimation calculation unit 100, a second SOG estimation calculation unit 200, and a control unit 300.

The first SOH estimation calculation unit 100 estimates a first battery state of health (SOH) using the SOC variation and the amount of electric charge during a specific time period on the basis of change in the SOC of the high-voltage vehicle battery 400 acquired according to a flow of a current during charge and discharge of the high-voltage vehicle battery 400.

If a first battery SOH estimated by the first SOH estimation calculation unit 100 satisfies a preset threshold condition (the first battery SOH is greater than a preset threshold value), the second SOH estimation calculation unit 200 minimizes an SOH error by estimating a second battery SOH through the least mean square method on the basis of the amount of electric charge and the SOC value corresponding to the first battery SOH value that satisfies the threshold condition.

The control unit 300 performs control such that the first SOH estimation calculation unit 100 and the second SOH estimation calculation unit 200 may perform their calculations.

For more detailed description, the control unit 300 measures a voltage (V) according to a flow of a voltage during charge and discharge of the high-voltage vehicle battery 400, estimates a no-load battery open circuit voltage (OCV) from the measured voltage (V), acquires a battery SOC corresponding to the estimated battery OCV on the basis of a predefined correlation (an SOC lookup table for each OCV) between the battery OCV and the SOC, and calculate a variation ΔSOC between the acquired SOC and the previously acquired SOC.

For example, when a battery state of charge SOCₙ₂ is acquired at timing n2, the control unit 300 calculates the variation ΔSOC in the battery SOC between the acquired SOCₙ₂ and a battery state of charge SOCₙ₁ acquired at timing n1 before timing n2 (ΔSOC=SOCₙ₁−SOCₙ₂).

The control unit 300 controls comparison of the calculated variation ΔSOC with a preset first threshold value, and if the calculated variation ΔSOC is greater than the preset first threshold value, allows the first SOH estimation calculation unit 100 to perform first SOH estimation calculation.

The first SOH estimation calculation unit 100 performs the first SOH estimation calculation according to the control of the control unit 300.

First, the first SOH estimation calculation unit 100 derives the capacity C′ of the high-voltage vehicle battery 400 according to the variation of the amount of electric charge on the basis of Equation (1) that is an SOC integral equation.

$$SOC ( n ) = SOC ( n - 1 ) + \frac{i Δ T}{C} \qquad ( 1 )$$

Here, i=Current (A), ΔT=Current application time (s), and c=battery capacity (Ah).

$${C}^{′} = \frac{{\sum }_{k = {n}_{1}}^{{n}_{2}} i ( k ) Δ T}{SOC ( {n}_{2} ) - SOC ( {n}_{1} )} \qquad ( 2 )$$

In order to calculate the capacity C′ of the high-voltage vehicle battery 400 on the basis of Equation (2), the first SOH estimation calculation unit 100 measures a current i(n2) at timing n2, multiplies a current application time ΔT by the measured current i(n2) to calculate the amount of electric charge i(n2)ΔT at timing n2, and integrates the calculated amount of electric charge i(n2)ΔT at timing n2 to the calculated amount of electric charge i(n1)ΔT at timing n1 before timing n2 to calculate the variation of the amount of charges.

The SOH estimation calculation unit 100 calculates the variation ΔSOC in the battery SOC between SOCₙ₂ acquired at timing n2 and SOCₙ₁ acquired at timing n1 before timing n2 and calculates the capacity C′ of the high-voltage vehicle battery 400 on the basis of the calculated variation ΔSOC in the battery SOC and the variation in the amount of electric charge calculated from timing n1 to timing n2.

As in Equation (3), the SOH estimation calculation unit 100 divides the capacity C′ of the high-voltage vehicle battery 400 by the initial capacity C of the high-voltage vehicle battery 400, converts the result value into a percentage, estimates the first SOH of the high-voltage vehicle battery 400, and delivers the estimated first SOS to the control unit 300.

$$SOH = \frac{{C}^{′}}{C} \qquad ( 3 )$$

The control unit 300 controls comparison of the first SOH estimated by the first SOH estimation calculation unit 100 with a preset second threshold, and if the estimated first SOH is greater than the preset second threshold value, allows the second SOH estimation calculation unit 200 to perform second SOH estimation calculation.

As the first and second threshold values are set to be high, the accuracy of the first and second SOHs increases, but the update time may be long. Accordingly, each threshold value is preset in consideration of an available region of the SOC.

The second SOH estimation calculation unit 200 performs the second SOH estimation calculation according to the control of the control unit 300, as below.

A correlation between the charge transfer and the variation in battery SOC is as shown in FIG. 3. Thus, the second SOH estimation calculation unit 200 may represent the calculated variation in the amount of electric charge using a charge transfer as in Equation (4), may divide the charge transfer by the variation in the battery SOC to calculate the capacity C′ of the high-voltage vehicle battery 400, and may represent the capacity C′ of the high-voltage vehicle battery 400 using a slope of a linear function including the charge transfer and the variation ΔSOC in the battery SOC on the basis of that a Y-axis indicating the charge transfer and an X-axis indicating the variation ΔSOC in the battery SOC.

$${C}^{′} = \frac{{\sum }_{k = n 1}^{n 2} i ( k ) Δ T}{SOC ( n 2 ) - SOC ( n 1 )} = \frac{ChargeTransfer}{Δ SOC} \\ {C}^{′} = \frac{ChargeTransfer}{Δ SOC} = \frac{y}{x} \qquad ( 4 )$$

The second SOH estimation calculation unit 200 uses the least mean square method to estimate the second SOH.

The least mean square method predicts an equation that can express data acquired through observation or experiment in order to analyze the acquired data and describe the analysis.

For example, as shown in FIG. 3, when the acquired data includes a coordinate (x₁, y₁), a coordinate (x₂, y₂), . . . , a coordinate (xₙ₁, yₙ₁), and a coordinate (xₙ₂, yₙ₂), the sum of square of the difference yᵢ−f(xᵢ) between a coordinate value y₁ corresponding to each point xᵢ (1<=i<=n2) and a function value f(xᵢ), that is, the sum of square of yᵢ−(axᵢ+b) should be minimized such that a linear equation f(x) for the acquired data may be equal to ax+b.

That is, when the above-described sum of square root is equal to Equation (5), and Equation (5) is minimized, the linear equation f(x) is equal to ax+b where a coordinate (x₁, y₁), a coordinate (x₂, y₂), . . . , a coordinate (xₙ₁, yₙ₁), and a coordinate (xₙ₂, yₙ₂) are described best.

$$E ( a , b ) = {\sum }_{i = 1}^{n} {( {y}_{i} - ( {ax}_{i} + b ) )}^{2} \qquad ( 5 )$$

A minimum value of E(a, b) is determined by a slope a and an intercept b of the line. As in FIG. 6, partial derivatives ∂E/∂a and ∂E/∂b should be equal to zero such that the value of E(a, b) may be minimum on the basis of fundamental theorem of calculus.

Accordingly, the second SOH estimation calculation unit 200 may derive the simultaneous equations such as Equation (7), from Equation (6) on the basis of the above description.

$$\begin{matrix}\begin{matrix}0 = \frac{\partial E}{\partial a} \\ = \sum 2 ( {y}_{i} - {ax}_{i} - b ) ( - {x}_{i} ) \\ = 2 ( a \sum {x}_{i}^{2} + b \sum {x}_{i} - \sum {x}_{i} {y}_{i} )\end{matrix} \\ \begin{matrix}0 = \frac{\partial E}{\partial b} \\ = \sum 2 ( {y}_{i} - {ax}_{i} - b ) ( - 1 ) \\ = 2 ( a \sum {x}_{i} + b \sum 1 - \sum {y}_{i} )\end{matrix} & ( 6 ) \\ a \sum {x}_{i}^{2} + b \sum {x}_{i} = \sum {x}_{i} {y}_{i} \\ a \sum {x}_{i} + b \sum 1 = \sum {y}_{i} & ( 7 )\end{matrix}$$

The second SOH estimation calculation unit 200 may convert Equation (7) into Equation (8) on the basis of a matrix.

$$[ \begin{matrix}\sum {x}_{i}^{2} & \sum {x}_{i} \\ \sum {x}_{i} & \sum 1\end{matrix} ] [ \begin{matrix}a \\ b\end{matrix} ] = [ \begin{matrix}\sum {x}_{i} {y}_{i} \\ \sum {y}_{i}\end{matrix} ] \qquad ( 8 )$$

Since a linear equation f(x) of the variation ΔSOC in the battery SOC vs. the charge transfer, that is, ax+b has a y-intercept (a value of b) of 0, the second SOH estimation calculation unit 200 may substitute a value of b with 0 in Equation (7) and then derive a value of a from Equation (9)

$${a}_{1} = \frac{\sum {x}_{i} {y}_{i}}{\sum {x}_{i}^{2}} \\ {a}_{2} = \frac{\sum {y}_{i}}{\sum {x}_{i}} \qquad ( 9 )$$

The second SOH estimation calculation unit 200 may find out from FIG. 3 that the slope a of the linear equation f(x) indicates the capacity C′ of the high-voltage vehicle battery 400, put the slope a of the linear equation f(x) as a₁ according to the least mean square method, and represent a₁ as the variation ΔSOC in the battery SOC vs. the charge transfer of Equation (10).

$$\begin{matrix}{C}^{′} = a ( slope of linear equation ) \\ = \frac{\sum {x}_{i} {y}_{i}}{\sum {x}_{i}^{2}} \\ = \frac{\sum Δ SOC \times Charge Transfer}{\sum Δ {SOC}^{2}}\end{matrix} \qquad ( 10 )$$

Accordingly, the second SOH estimation calculation unit 200 may calculate a capacity C′ of the high-voltage vehicle battery 400 from Equation (10), divide the calculated capacity C′ of the high-voltage vehicle battery 400 by the initial capacity C of the high-voltage vehicle battery 400, and convert the division result into a percentage to estimate a second SOH.

As described above, according to the present invention, it is possible to calculate a battery capacity with only a current value and an SOC variation value to estimate the battery SOH, thereby simplifying an estimation algorithm. In particular, it is possible to estimate the battery SOH through the first estimation algorithm, compare the estimated battery SOH with a threshold value, determine whether to perform re-estimation, and if the re-estimation is determined, re-estimate the battery SOH through a second estimation algorithm, using a least mean square method, thereby minimizing an error of a battery SOH estimation value.

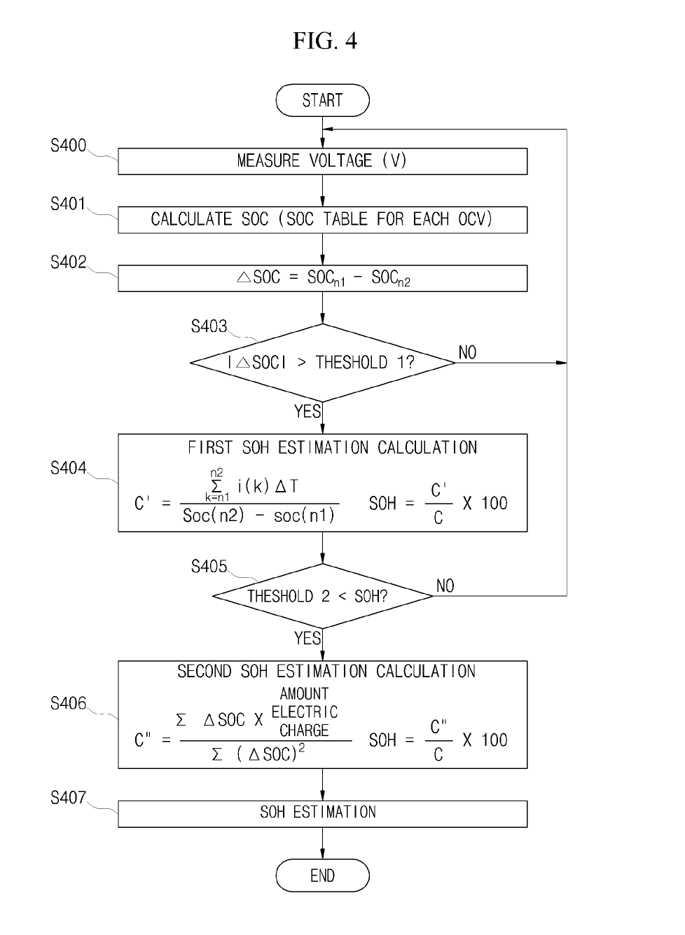

The apparatus for determining degradation of a high-voltage vehicle battery according to an embodiment of the present invention has been described with reference to FIGS. 2 and 3. Hereinafter, the method of determining degradation of a high-voltage vehicle battery according to an embodiment of the present invention will be described with reference to FIG. 4. FIG. 4 is a flowchart showing a method of determining degradation of a high-voltage vehicle battery according to an embodiment of the present invention.

As shown in FIG. 4, the method measures a voltage (V) according to a flow of a voltage during charge and discharge of the high-voltage vehicle battery 400 in operation S400, estimates a no-load battery open circuit voltage (OCV) from the measured voltage (V) and acquires a battery SOC corresponding to the estimated battery OCV on the basis of a predefined correlation (an SOC lookup table for each OCV) between the battery OCV and the SOC in operation S401, and calculates the variation ΔSOC between the acquired SOC and the previously acquired SOC in operation S402.

For example, when a battery state of charge SOCₙ₂ is acquired at timing n2, the method calculates the variation ΔSOC in the battery SOC between the acquired SOCₙ₂ and a battery state of charge SOCₙ₁ acquired at timing n1 before timing n2 (ΔSOC=SOCₙ₁−SOCₙ₂).

The method determines whether the calculated variation ΔSOC is greater than a preset first threshold value in operation S403, and if the calculated variation ΔSOC is greater than the preset first threshold value, performs first SOH estimation calculation in operation S404.

The first SOH estimation calculation is as follows.

First, as in Equation (2), the first SOH estimation calculation may include deriving the capacity C′ of the high-voltage vehicle battery 400 according to the variation of the amount of electric charge on the basis of Equation (1) that is an SOC current integral equation.

In order to calculate the capacity C′ of the high-voltage vehicle battery 400 on the basis of Equation (2), the first SOH estimation calculation includes measuring a current i(n2) at timing n2, multiplying a current application time ΔT by the measured current i(n2) to calculate the amount of electric charge i(n2)ΔT at timing n2, and integrating the calculated amount of electric charge i(n2)ΔT at timing n2 to the calculated amount of electric charge i(n1)ΔT at timing n1 to calculate the variation of the amount of charges.

The SOH estimation calculation may include calculating the variation ΔSOC in the battery SOC between SOCₙ₂ acquired at timing n2 and SOCₙ₁ acquired at timing n1 before timing n2 and calculates the capacity C′ of the high-voltage vehicle battery 400 on the basis of the calculated variation ΔSOC in the battery SOC and the variation in the amount of electric charge calculated from timing n1 to timing n2.

As in Equation (3), the SOH estimation calculation includes dividing the capacity C′ of the high-voltage vehicle battery 400 by the initial capacity C of the high-voltage vehicle battery 400, converting the result value into a percentage, and estimating the first SOH.

The SOH estimation calculation includes determining whether the estimated first SOH is greater than a preset second threshold value in operation S405, and if the estimated first SOH is greater than the preset second threshold value, performing second SOH estimation calculation in operation S406.

The second SOH estimation calculation is as follows.

A correlation between the charge transfer and the variation in the battery SOC is as shown in FIG. 3.

That is, the second SOH estimation calculation may include representing the calculated variation in the amount of electric charge using a charge transfer as in Equation (4), dividing the charge transfer by the variation in the battery SOC to calculate the capacity C′ of the high-voltage vehicle battery 400, and representing the capacity C′ of the high-voltage vehicle battery 400 using a slope of a linear function including the charge transfer and the variation ΔSOC in the battery SOC on the basis of that a Y-axis indicating the charge transfer and an X-axis indicating the variation ΔSOC in the battery SOC.

The least mean square method predicts an equation that can express data acquired through observation or experiment in order to analyze the acquired data and describe the analysis.

For example, as shown in FIG. 3, when the acquired data includes a coordinate (x₁, y₁), a coordinate (x₂, y₂), . . . , a coordinate (xₙ₁, yₙ₁), and a coordinate (xₙ₂, yₙ₂), the sum of square of the difference yᵢ−f(xᵢ) between a coordinate value y₁ corresponding to each point xᵢ (1<=i<=n2) and a function value f(xᵢ), that is, the sum of square of yᵢ−(axᵢ+b) should be minimized such that a linear equation f(x) for the acquired data may be equal to ax+b.

That is, when Equation (5) is minimized, the linear equation f(x) is equal to ax+b where a coordinate (x₁, y₁), a coordinate (x₂, y₂), . . . , a coordinate (xₙ₁, yₙ₁), and a coordinate (xₙ₂, yₙ₂) are described best.

As described above, in Equation (5) indicating an optimized least square line, a minimum value of E(a, b) is determined by a slope a and an intercept b of the line. As in FIG. 6, partial derivatives ∂E/∂a and ∂E/∂b should be equal to zero such that the value of E(a, b) may be minimum. Accordingly, simultaneous equations such as Equation (7) may be derived from Equation (6).

Since a linear equation f(x) of the variation ΔSOC in the battery SOC vs. the charge transfer, that is, ax+b has a y-intercept (a value of b) of 0, b is substituted with 0 in Equation (7), and thus a is as in Equation (9).

It can be seen from FIG. 3 that the slope a of the linear equation f(x) indicates the capacity C′ of the high-voltage vehicle battery 400, and if the slope a of the linear equation f(x) is a₁ according to the least mean square method, Equation (9) may be represented as the variation ΔSOC in the battery SOC vs. the charge transfer in Equation (10).

Accordingly, the second SOH estimation calculation includes calculating the capacity C′ of the high-voltage vehicle battery 400 from Equation (10), dividing the calculated capacity C′ of the high-voltage vehicle battery 400 by the initial capacity of the high-voltage vehicle battery 400, and converting the division result into percentage to estimate a second SOH in operation S407.

According to the present invention, it is possible to calculate a capacity of a battery only using a current value and an SOC change value to estimate an SOH of the battery, thereby simplifying an algorithm for estimation.

In particular, it is also advantageously possible to estimate a battery SOH through a first estimation algorithm, compare the estimated battery SOH with a threshold value, determine whether to perform re-estimation, and if the re-estimation is determined, re-estimate the battery SOH through a second estimation algorithm, using a least mean square method, thereby minimizing an error in a battery SOH estimation value.

It should be understood that although the present invention has been described above in detail with reference to the accompanying drawings and exemplary embodiments, this is illustrative only and various modifications may be made without departing from the spirit or scope of the invention. Thus, the scope of the present invention is to be determined by the following claims and their equivalents, and shall not be restricted or limited by the foregoing detailed description.

What is claimed is:

1. An apparatus for determining degradation of a high-voltage vehicle battery, the apparatus comprising:
a first SOH estimation calculation unit configured to estimate a first battery state of health (SOH) on a basis of a variation in a state of charge (SOC) of the high-voltage vehicle battery and an amount of electric charge during a specific time calculated according to a flow of a current during charge and discharge of the high-voltage vehicle battery;
a second SOH estimation calculation unit configured to estimate a second battery SOH through a least mean square method on a basis of the variation in the battery SOC and the amount of electric charge during the specific time corresponding to the estimated first battery SOH; and
a control unit configured to allow the first SOH estimation calculation unit and the second SOH estimation calculation unit to estimate the battery SOHs, respectively, in order to minimize an error in the finally estimated battery SOH.

2. The apparatus of claim 1, wherein the control unit estimates a battery open circuit voltage (OCV) on a basis of a voltage (V) according to a flow of a voltage during charge and discharge of the high-voltage vehicle battery, acquires a state of charge (SOC) of the high-voltage vehicle battery corresponding to the estimated battery OCV on a basis of a predefined SOC lookup table for each OCV, calculates a variation ΔSOC between the acquired SOC of the high-voltage vehicle battery and a previously acquired SOC of the high-voltage vehicle battery, compares the calculated variation ΔSOC with a preset first threshold value, and if the calculated variation ΔSOC is greater than the first threshold value, allows the first SOH estimation calculation unit to estimate the first battery SOH.

3. The apparatus of claim 1, wherein the first SOH estimation calculation unit calculates a variation ΔSOC in an SOC of the high-voltage vehicle battery between SOCₙ₂ acquired at timing n2 and SOCₙ₁ acquired at timing n1 before timing n2 on a basis of an SOC current integral equation, calculates a capacity C′ of the high-voltage vehicle battery on a basis of a variation in the amount of electric charge calculated from timing n1 to timing n2, divides the calculated capacity C′ of the high-voltage vehicle battery by an initial capacity C of the high-voltage vehicle battery, converts the division result into a percentage, estimates a first battery SOH of the high-voltage vehicle battery, and delivers the first battery SOH to the control unit.

4. The apparatus of claim 3, wherein the control unit compares the first battery SOH estimated by the first SOH estimation calculation unit with a preset second threshold value, and if the first battery SOH is greater than the second threshold value, allows the second SOH estimation calculation unit to estimate a second battery SOH.

5. The apparatus of claim 1, wherein,
$$\begin{matrix}E ( a , b ) = {\sum }_{i = 1}^{n} {( {y}_{i} - ( {ax}_{i} + b ) )}^{2} \\ \begin{matrix}0 = \frac{\partial E}{\partial a} \\ = \sum 2 ( {y}_{i} - {ax}_{i} - b ) ( - {x}_{i} ) \\ = 2 ( a \sum {x}_{i}^{2} + b \sum {x}_{i} - \sum {x}_{i} {y}_{i} )\end{matrix} & ( 5 ) \\ \begin{matrix}0 = \frac{\partial E}{\partial b} \\ = \sum 2 ( {y}_{i} - {ax}_{i} - b ) ( - 1 ) \\ = 2 ( a \sum {x}_{i} + b \sum 1 - \sum {y}_{i} )\end{matrix} & ( 6 ) \\ a \sum {x}_{i}^{2} + b \sum {x}_{i} = \sum {x}_{i} {y}_{i} \\ a \sum {x}_{i} + b \sum 1 = \sum {y}_{i} & ( 7 ) \\ {a}_{1} = \frac{\sum {x}_{i} {y}_{i}}{\sum {x}_{i}^{2}} \\ {a}_{2} = \frac{\sum {y}_{i}}{\sum {x}_{i}} & ( 9 ) \\ \begin{matrix}{C}^{′} = a ( slope of linear equation ) \\ = \frac{\sum {x}_{i} {y}_{i}}{\sum {x}_{i}^{2}} \\ = \frac{\sum Δ SOC \times Charge Transfer}{\sum Δ {SOC}^{2}}\end{matrix} & ( 10 )\end{matrix}$$
the second SOH estimation calculation unit derives simultaneous equations such as Equation (7) from Equations (5) and (6) on a basis of a least mean square, derives Equation (9) by substituting b of Equation (7) with 0, represents a₁ of Equation (9) as a correlation between the charge transfer and the variation ΔSOC in the SOC of the high-voltage vehicle battery of Equation (10), calculates a capacity C′ of the high-voltage vehicle battery from Equation (10), divides the calculated capacity C′ of the high-voltage vehicle battery by an initial capacity of the high-voltage vehicle battery, converts the division result into a percentage, and estimates a second battery SOH.

6. A method of determining degradation of a high-voltage vehicle battery, the method comprising:
estimating a first battery state of health (SOH) on a basis of a variation in a battery state of charge (SOC) of the high-voltage vehicle battery and an amount of electric charge during a specific time calculated according to a flow of a current during charge and discharge of the high-voltage vehicle battery; and
estimating a second battery SOH through a least mean square method on a basis of the variation in the battery SOC and the amount of electric charge during the specific time corresponding to the estimated first battery SOH.

7. The method of claim 6, further comprising:
estimating a battery open circuit voltage (OCV) on a basis of a voltage (V) according to a flow of a voltage during charge and discharge of the high-voltage vehicle battery;
acquiring a state of charge (SOC) of the high-voltage vehicle battery corresponding to the estimated battery OCV on a basis of a predefined SOC lookup table for each OCV;
calculating a variation ΔSOC between the acquired SOC of the high-voltage vehicle battery and a previously acquired SOC of the high-voltage vehicle battery and comparing the calculated variation ΔSOC with a preset first threshold value; and
if the calculated variation ΔSOC is greater than the first threshold value, controlling estimation of the first battery SOH.

8. The method of claim 6, wherein the estimating of a first battery SOH comprises:
calculating a variation ΔSOC in an SOC of the high-voltage vehicle battery between SOCₙ₂ acquired at timing n2 and SOCₙ₁ acquired at timing n1 before timing n2 on a basis of an SOC current integral equation and calculating a capacity C′ of the high-voltage vehicle battery on a basis of a variation in the amount of electric charge calculated from timing n1 to timing n2; and
dividing the calculated capacity C′ of the high-voltage vehicle battery by an initial capacity C of the high-voltage vehicle battery, converting the division result into a percentage, and estimating a first battery SOH of the high-voltage vehicle battery.

9. The method of claim 8, further comprising:
comparing the estimated first battery SOH with a preset second threshold value, and
if the estimated first battery SOH is greater than the preset second threshold value, allowing the second SOH estimation calculation unit to estimate a second battery SOH.

10. The method of claim 6, wherein the estimating of a second battery SOH comprises:
$$\begin{matrix}E ( a , b ) = {\sum }_{i = 1}^{n} {( {y}_{i} - ( {ax}_{i} + b ) )}^{2} \\ \begin{matrix}0 = \frac{\partial E}{\partial a} \\ = \sum 2 ( {y}_{i} - {ax}_{i} - b ) ( - {x}_{i} ) \\ = 2 ( a \sum {x}_{i}^{2} + b \sum {x}_{i} - \sum {x}_{i} {y}_{i} )\end{matrix} & ( 5 ) \\ \begin{matrix}0 = \frac{\partial E}{\partial b} \\ = \sum 2 ( {y}_{i} - {ax}_{i} - b ) ( - 1 ) \\ = 2 ( a \sum {x}_{i} + b \sum 1 - \sum {y}_{i} )\end{matrix} & ( 6 ) \\ a \sum {x}_{i}^{2} + b \sum {x}_{i} = \sum {x}_{i} {y}_{i} \\ a \sum {x}_{i} + b \sum 1 = \sum {y}_{i} & ( 7 ) \\ {a}_{1} = \frac{\sum {x}_{i} {y}_{i}}{\sum {x}_{i}^{2}} \\ {a}_{2} = \frac{\sum {y}_{i}}{\sum {x}_{i}} & ( 9 ) \\ \begin{matrix}{C}^{′} = a ( slope of linear equation ) \\ = \frac{\sum {x}_{i} {y}_{i}}{\sum {x}_{i}^{2}} \\ = \frac{\sum Δ SOC \times Charge Transfer}{\sum Δ {SOC}^{2}}\end{matrix} & ( 10 )\end{matrix}$$
deriving simultaneous equations such as Equation (7) from Equations (5) and (6) on a basis of the least mean square method;
deriving Equation (9) by substituting b of Equation (7) with 0;
representing a₁ of Equation (9) as a correlation between the charge transfer and the variation ΔSOC in the SOC of the high-voltage vehicle battery of Equation (10) and calculating a capacity C′ of the high-voltage vehicle battery from Equation (10); and
dividing the calculated capacity C′ of the high-voltage vehicle battery by an initial capacity of the high-voltage vehicle battery, converting the division result into a percentage, and estimating a second battery SOH.
